(19) United States
(12) Patent Application Publication
(10) Pub. No.: US 2016/0254284 A1
(43) Pub. Date: Sep. 1, 2016

(54) ARRAY SUBSTRATE, METHOD OF PREPARING THE SAME, AND DISPLAY DEVICE

(71) Applicant: SHENZHEN CHINA STAR OPTOELECTRONICS TECHNOLOGY CO., LTD., Shenzhen, Guangdong (CN)

(72) Inventor: Guo ZHAO, Shenzhen (CN)

(21) Appl. No.: 14/417,955

(22) PCT Filed: Aug. 25, 2014
(86) PCT No.: PCT/CN2014/085123

§ 371 Date: Mar. 7, 2016

(30) Foreign Application Priority Data
Aug. 14, 2014 (CN) 201410399880.4

(51) Int. Cl. H01L 27/12; G02F 1/1333; G02F 1/1362; G02F 1/1335

(52) U.S. Cl. CPC H01L 27/1244; H01L 27/1262; G02F 1/133514; G02F 1/133345; G02F 1/136227

(57) ABSTRACT

The present disclosure belongs to the field of display technologies, discloses an array substrate, a method of preparing the same, and a display device, and solves the technical problem of a large contact resistance between a pixel electrode and a drain of a TFT. The array substrate comprises a metal pattern, an insulation layer covering the metal pattern, and an electrode pattern formed on the insulation layer. The insulation layer is provided with a via hole, through which the electrode pattern is electrically connected to the metal pattern. A part of region occupied by the via hole overlaps the metal pattern, and the remaining part of said region occupied by the via hole extends outside of the metal pattern. The present disclosure can be used in display devices such as a liquid crystal television, a liquid crystal display, a mobile phone, and a tablet PC.

The present application claims benefit of Chinese patent application CN 201410399880.4, entitled “Array substrate, method of preparing the same, and display device” and filed on Aug. 14, 2014, the entirety of which is incorporated herein by reference.

### FIELD OF THE INVENTION

The present disclosure relates to the field of display technologies, in particular to an array substrate, a method of preparing the same, and a display device.

### BACKGROUND OF THE INVENTION

The development of display technologies makes liquid crystal displays a most commonly used panel display device.

A liquid crystal display usually comprises an array substrate, a color filter substrate, etc., wherein the array substrate is provided with layer structures such as a gate metal layer, a source/drain metal layer, a transparent electrode layer, and a passivation layer, with different layers connected to one another through via holes. As shown in FIGS. 1 and 2, a via hole 6 is arranged on a passivation layer 4 which is placed between a drain 3 of a thin film transistor (TFT) and a pixel electrode 5 (located on a transparent electrode layer), so that the pixel electrode 5 is electrically connected to the drain 3 of the TFT through the via hole 6.

However, when the via hole 6 is being etched into the passivation layer 4, the drain 3 of the TFT may be partially etched away also. As a result, the contact surface between the pixel electrode 5 and the drain 3 of the TFT would form a rather steep angle. Moreover, the drain 3 of the TFT can be etched to form a chamfer, causing the pixel electrode 5 to be broken. Under such circumstances, contact resistance between the pixel electrode 5 and the drain 3 of the TFT would be increased, thus negatively influencing display effects of the liquid crystal display.

### SUMMARY OF THE INVENTION

According to the present disclosure, it aims to provide an array substrate, a method of preparing the same, and a display device, so as to solve the technical problem of large contact resistance between a pixel electrode and the drain of a TFT.

The present disclosure provides an array substrate, comprising a metal pattern, an insulation layer covering the metal pattern, and an electrode pattern formed on the insulation layer. The insulation layer is provided with a via hole, through which the electrode pattern is electrically connected to the metal pattern. A part of region occupied by the via hole overlaps the metal pattern, and the remaining part of said region extends outside of the metal pattern.

Preferably, said region occupied by the via hole corresponds to an edge of the metal pattern.

Preferably, said region occupied by the via hole has a width greater than the width of the metal pattern, and a central portion of said region occupied by the via hole overlaps the metal pattern, and two end portions of said region extend outside of the metal pattern.

Preferably, the metal pattern constitutes the drain of a thin film transistor, and the electrode pattern is in the form of a pixel electrode.

The present disclosure further provides a method of preparing an array substrate, comprising:
forming a metal pattern;
covering the metal pattern with an insulation layer;
etching the insulation layer to form a via hole, wherein a part of region occupied by the via hole overlaps the metal pattern, and the remaining part of said region occupied by the via hole extends outside of the metal pattern; and
forming an electrode pattern on the insulation layer, so that the electrode pattern can be electrically connected the metal pattern through the via hole.

Preferably, said region occupied by the via hole corresponds to an edge of the metal pattern.

Preferably, said region occupied by the via hole has a width greater than the width of the metal pattern, and a central portion of said region occupied by the via hole overlaps the metal pattern, and two end portions of said region extend outside of the metal pattern.

Preferably, the metal pattern constitutes the drain of a thin film transistor, and the electrode pattern is in the form of a pixel electrode.

The present disclosure further provides a display device, comprising a color filter substrate and the array substrate as described above.

The present disclosure has brought about the following beneficial effects. In the array substrate of the present disclosure, the electrode pattern is electrically connected to the metal pattern through the via hole arranged on the insulation layer, wherein a part of region occupied by the via hole overlaps the metal pattern, and the remaining part of said region occupied by the via hole extends outside of the metal pattern. When the via hole is being etched on the insulation layer, the metal pattern will be etched with a gentle slope, which constitutes a contact surface between the metal pattern and the electrode pattern. Consequently, the embodiments of the present disclosure provide a technical solution in which a gentle slope is formed as the contact surface between the metal pattern and the electrode pattern, thus preventing the pixel electrode from being broken and reducing contact resistance between the metal pattern and the pixel electrode pattern. The technical problem in the prior art that the display effects are negatively influenced due to large contact resistance between the pixel electrode and the drain of the TFT can therefore be solved.

Other features and advantages of the present disclosure will be illustrated and become partially obvious in the following description, and be understood through implementation of the present disclosure. The purposes and other advantages of the present disclosure will be achievable or obtainable through the structures as indicated in the following description, claims, and drawings.

### BRIEF DESCRIPTION OF THE DRAWINGS

In order to elucidate the technical solution contained in the embodiments of the present disclosure explicitly, the drawings referred to thereby will be briefly explained, wherein:

FIG. 1 schematically shows a partial view of an existing array substrate;

FIG. 2 is a cross-section view of the array substrate as shown in FIG. 1 along line A-A;

FIG. 3 schematically shows a partial view of an array substrate provided in Embodiment 1 of the present disclosure;

FIG. 4 is a cross-section view of the array substrate as shown in FIG. 3 along line A-A;

FIG. 5 schematically shows a partial view of an array substrate provided in Embodiment 2 of the present disclosure;

FIG. 6 is a cross-section view of the array substrate as shown in FIG. 5 along line B-B;

FIG. 7 schematically shows a partial view of an array substrate provided in Embodiment 3 of the present disclosure;

FIG. 8 is a cross-section view of the array substrate as shown in FIG. 7 along line A-A; and

FIG. 9 is a cross-section view of the array substrate as shown in FIG. 7 along line B-B.

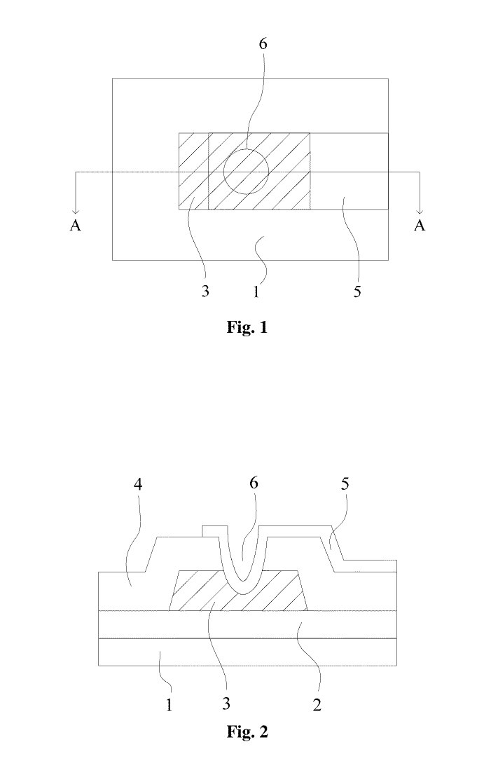

### DETAILED DESCRIPTION OF THE EMBODIMENTS

The present disclosure will be explained by reference to the following detailed description of embodiments taken in connection with the accompanying drawings, whereby it can be readily understood how to solve the technical problem by the technical means according to the present disclosure and achieve the technical effects thereof, and thus the technical solution according to the present disclosure can be implemented. It is important to note that as long as there is no conflict, combinations of the above-described embodiments and of technical features therein are possible, and technical solutions obtained in this manner are intended to be within the scope of the present disclosure.

The present disclosure provides an array substrate, comprising a metal pattern, an insulation layer covering the metal pattern, and an electrode pattern formed on the insulation layer. The insulation layer is provided with a via hole, through which the electrode pattern is electrically connected to the metal pattern. A part of region occupied by the via hole overlaps the metal pattern, and the remaining part of said region extends outside of the metal pattern.

In the array substrate provided by the embodiments of the present disclosure, the electrode pattern is electrically connected to the metal pattern through the via hole provided on the insulation layer. A part of region occupied by the via hole overlaps the metal pattern, and the remaining part of said region extends outside of the metal pattern. When the via hole is being etched into the insulation layer, the metal pattern will be etched with a gentle slope, which constitutes the contact surface between the metal pattern and the electrode pattern. Consequently, the embodiments of the present disclosure provide a technical solution in which a gentle slope is formed as the contact surface between the metal pattern and the electrode pattern, thus preventing the pixel electrode from being broken and reducing contact resistance between the metal pattern and the pixel electrode pattern. The technical problem in the prior art that the display effects are negatively influenced due to large contact resistance between the pixel electrode and the drain of the TFT can therefore be solved.

### Embodiment 1

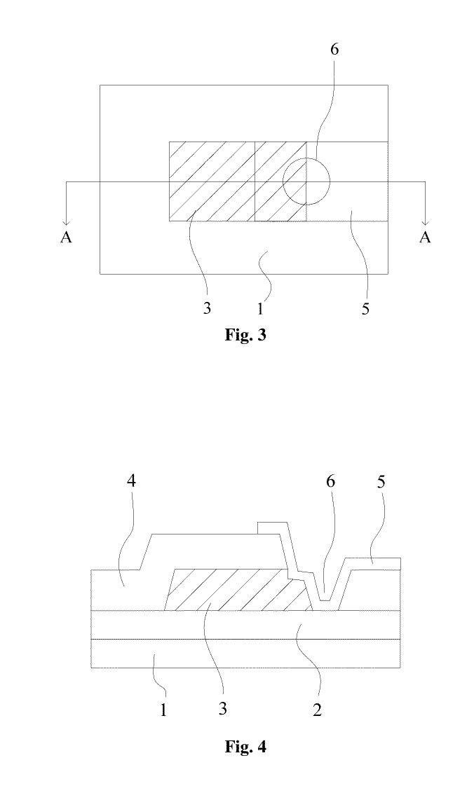

As indicated in FIGS. 3 and 4, this embodiment of the present disclosure provides an array substrate comprising a gate metal layer (not shown in the drawings) formed on a base substrate 1, a gate insulation layer 2, a data line metal layer (including a data line, a source and a drain 3 of a TFT, etc.), a passivation layer 4, a pixel electrode 5, and other structures.

The passivation layer 4 is provided with a via hole 6, through which the pixel electrode 5 is electrically connected to the drain 3 of the TFT. Moreover, a region occupied by the via hole 6 corresponds to an edge of the drain 3, and thus a part of said region overlaps the drain 3, and the remaining part thereof extends outside of the drain 3.

In the array substrate of this embodiment of the present disclosure, the pixel electrode 5 is electrically connected to the drain 3 through the via hole 6 arranged on the passivation layer 4, and the region occupied by the via hole 6 corresponds to the edge of the drain 3. When the via hole 6 is being etched into the passivation layer 4, the drain 3 will be etched with a horizontal plane or a gentle slope, which constitutes a contact surface between the drain 3 and the pixel electrode 5.

In case the drain 3 is not etched or only slightly etched away when the via hole 6 is being etched, a horizontal upper surface of the drain 3 will appear in the region occupied by the via hole 6. In this case, the contact surface between the pixel electrode 5 and the drain 3 will thus be a horizontal plane.

Hence, in the array substrate of this embodiment of the present disclosure, the contact surface between the drain 3 and the pixel electrode 5 can be a horizontal plane or a gentle slope, thus preventing the pixel electrode 5 from being broken and reducing contact resistance between the drain 3 and the pixel electrode 5. The technical problem in the prior art that the display effects are negatively influenced due to large contact resistance between the pixel electrode and the drain of the TFT can therefore be solved.

This embodiment of the present disclosure further provides a method of preparing the above array substrate, including the following steps.

In Step (1), a gate metal layer is formed on a base substrate 1 via a patterning procedure.

In Step (2), the gate metal layer is covered with an insulation layer 2.

In Step (3), a data line metal layer comprising a data line, a source of a TFT, a drain 3 of the TFT, and other structures is formed on the insulation layer 2 via a patterning procedure.

In Step (4), the data line metal layer is covered by a passivation layer 4.

In Step (5), the passivation layer 4 is etched via a patterning procedure to form a via hole 6.

A region occupied by the via hole 6 corresponds to an edge of the drain 3, and thus a part of said region overlaps the drain 3 and the remaining part thereof extends outside of the drain 3.

When the via hole 6 is being etched, the drain 3 will be etched with a horizontal plane or a gentle slope. In case the drain 3 is not etched or only slightly etched away, an upper surface of the drain 3 will appear in the region occupied by the via hole 6.

In Step (6), a pixel electrode 5 is formed on the passivation layer 4 via a patterning procedure, and electrically connected to the drain 3 through the via hole 6.

The array substrate of this embodiment can be formed through some subsequent conventional steps. In this array substrate, the contact surface between the drain 3 and the pixel electrode 5 is a horizontal plane or a gentle slope, thus preventing the pixel electrode 5 from being broken and reducing contact resistance between the drain 3 and the pixel electrode 5. The technical problem in the prior art that the display effects are negatively influenced due to large contact resistance between the pixel electrode and the drain of the TFT can thus be solved.

### Embodiment 2

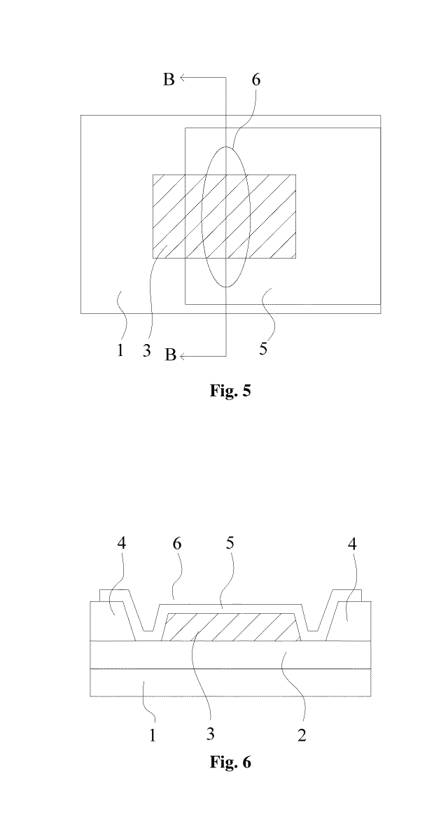

As indicated in FIGS. 5 and 6, this embodiment of the present disclosure provides an array substrate comprising a gate metal layer (not shown in the drawings) formed on a base substrate 1, a gate insulation layer 2, a data line metal layer (including a data line, a source and a drain 3 of a TFT, etc.), a passivation layer 4, a pixel electrode 5, and other structures.

The passivation layer 4 is provided with a via hole 6, through which the pixel electrode 5 is electrically connected to the drain 3 of the TFT. In this embodiment, the width of the via hole 6 is increased. Meanwhile, the width of the drain 3 can be appropriately reduced, so that a region occupied by the via hole 6 can have a width greater than the width of the drain 3. Therefore, a central portion of said region occupied by the via hole 6 overlaps the drain 3, and two end portions of said region extend outside of the drain 3.

In the array substrate of this embodiment of the present disclosure, the pixel electrode 5 is electrically connected to the drain 3 through the via hole 6 provided on the passivation layer 4, wherein the via hole 6 has two ends extending outside of an edge of the drain 3. When the via hole 6 is being etched into the passivation layer 4, the drain 3 will be etched with a large horizontal plane, which constitutes a contact surface between the drain 3 and the pixel electrode 5.

In case the drain 3 is not etched or only slightly etched away when the via hole 6 is being etched, a horizontal upper surface of the drain 3 will appear in the region occupied by the via hole 6. In this case, the contact surface between the pixel electrode 5 and the drain 3 will thus be a horizontal plane.

Consequently, in the array substrate according to this embodiment of the present disclosure, the contact surface between the drain 3 and the pixel electrode 5 can be a large horizontal plane, thus not only increasing the contact area between the drain 3 and the pixel electrode 5, but also preventing the pixel electrode 5 from being broken. As a result, the contact resistance between the drain 3 and the pixel electrode 5 can be reduced. The technical problem in the prior art that the display effects are negatively influenced due to large contact resistance between the pixel electrode and the drain of the TFT can therefore be solved.

This embodiment of the present disclosure further provides a method of preparing the above array substrate, including the following steps.

In Step (1), a gate metal layer is formed on a base substrate 1 via a patterning procedure.

In Step (2), the gate metal layer is covered with an insulation layer 2.

In Step (3), a data line metal layer comprising a data line, a source of the TFT, a drain 3, and other structures is formed on the insulation layer 2 via a patterning procedure.

In Step (4), the data line metal layer is covered by a passivation layer 4.

In Step (5), the passivation layer 4 is etched via a patterning procedure to form a via hole 6.

A region occupied by the via hole 6 has a width greater than the width of the drain 3, and a central portion of said region occupied by the via hole 6 overlaps the drain 3, and two end portions of said region extend outside of the drain 3.

When the via hole 6 is being etched, the drain 3 will be etched with a large horizontal plane. In case the drain 3 is not etched or only slightly etched away, a horizontal upper surface of the drain 3 will appear in the region occupied by the via hole 6.

In Step (6), a pixel electrode 5 is formed on the passivation layer 4 via a patterning procedure, and electrically connected to the drain 3 through the via hole 6.

The array substrate of this embodiment can be formed through some subsequent conventional steps. In the array substrate, the contact surface between the drain 3 and the pixel electrode 5 is a large horizontal plane, thus not only increasing the contact area between the drain 3 and the pixel electrode 5, but also capable of preventing the pixel electrode 5 from being broken. As a result, the contact resistance between the drain 3 and the pixel electrode 5 can be reduced. The technical problem in the prior art that the display effects are negatively influenced due to large contact resistance between the pixel electrode and the drain of the TFT can therefore be solved.

### Embodiment 3

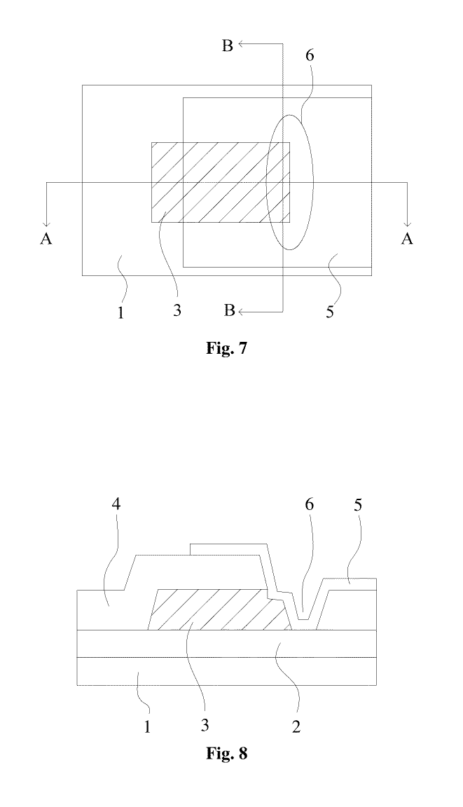

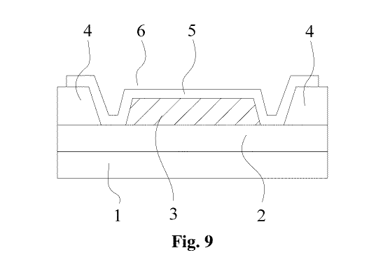

As indicated in FIGS. 7, 8, and 9, this embodiment of the present disclosure provides an array substrate, which has a structure that can be deemed as a combination of the structures of Embodiments 1 and 2. The array substrate comprises a gate metal layer (not shown in the drawings) formed on a base substrate 1, a gate insulation layer 2, a data line metal layer (including a data line, a source and a drain 3 of a TFT, etc.), a passivation layer 4, a pixel electrode 5, and other structures.

The passivation layer 4 is provided with a via hole 6, through which the pixel electrode 5 is electrically connected to the drain 3 of the TFT. In this embodiment, a region occupied by the via hole 6 corresponds to an edge of the drain 3. And the region occupied by the via hole 6 has a width greater than the width of the drain 3, so that two end portions of said region extend outside of the drain 3, and a part of the central portion of said region extends outside of the drain 3 and another part of the central portion overlaps the drain 3.

In the array substrate according to this embodiment of the present disclosure, the contact surface between the drain 3 and the pixel electrode 5 is a large horizontal plane or a slope, thus preventing the pixel electrode 5 from being broken and reducing the contact resistance between the drain 3 and the pixel electrode 5. The technical problem in the prior art that the display effects are negatively influenced due to large contact resistance between the pixel electrode and the drain of the TFT can therefore be solved.

It should be noted that the above three embodiments all take connection between the drain of a TFT and a pixel electrode in a pixel unit as an example. A metal pattern on another portion of the array substrate (such as a substrate edge wiring region and an impedance test region) can also be electrically connected to the electrode pattern through a via hole arranged in the same way. In this manner, the technical problem in the prior art that display effects are negatively influenced due to large contact resistance between the pixel electrode and the drain of the TFT can therefore be solved.

### Embodiment 4

This embodiment of the present disclosure provides a display device, which can specially be a liquid crystal television, a liquid crystal display, a mobile phone, a tablet PC, etc. The display device comprises a color filter substrate, and the array substrate as described above in Embodiment 1, 2, or 3.

The display device of this embodiment have the same technical features as the array substrate described in the above embodiments, and therefore can solve the same technical problem, and achieve the same technical effects.

While the embodiments of the present disclosure are described above, the description should not be construed as limitations of the present disclosure, but merely as embodiments for readily understanding the present disclosure. Anyone skilled in the art, within the spirit and scope of the present disclosure, can make amendments or modification to the implementing forms and details of the embodiments. Hence, the scope of the present disclosure should be subjected to the scope defined in the claims.

1. An array substrate, comprising a metal pattern, an insulation layer covering the metal pattern, and an electrode pattern formed on the insulation layer,
wherein the insulation layer is provided with a via hole, through which the electrode pattern is electrically connected to the metal pattern, and
a part of region occupied by the via hole overlaps the metal pattern, and the remaining part of said region occupied by the via hole extends outside of the metal pattern.

2. The array substrate of claim 1, wherein said region occupied by the via hole corresponds to an edge of the metal pattern.

3. The array substrate of claim 1, wherein said region occupied by the via hole has a width greater than the width of the metal pattern, and
a central portion of said region occupied by the via hole overlaps the metal pattern, and two end portions of said region extend outside of the metal pattern.

4. The array substrate of claim 1, wherein the metal pattern constitutes the drain of a thin film transistor, and the electrode pattern is in the form of a pixel electrode.

5. A method of preparing an array substrate, comprising:
forming a metal pattern;
covering the metal pattern with an insulation layer;
etching the insulation layer to form a via hole, wherein a part of region occupied by the via hole overlaps the metal pattern, and the remaining part of said region occupied by the via hole extends outside of the metal pattern; and
forming an electrode pattern on the insulation layer, so that the electrode pattern can be electrically connected the metal pattern through the via hole.

6. The method of claim 5, wherein said region occupied by the via hole corresponds to an edge of the metal pattern.

7. The method of claim 5, wherein said region occupied by the via hole has a width greater than the width of the metal pattern, and
a central portion said region occupied by the via hole overlaps the metal pattern, and two end portions of said region extend outside of the metal pattern.

8. The method of claim 5, wherein the metal pattern constitutes the drain of a thin film transistor, and the electrode pattern is in the form of a pixel electrode.

9. A display device, comprising a color filter substrate and an array substrate that has a metal pattern, an insulation layer covering the metal pattern, and an electrode pattern formed on the insulation layer,
wherein the insulation layer is provided with a via hole, through which the electrode pattern is electrically connected to the metal pattern, and
a part of region occupied by the via hole overlaps the metal pattern, and the remaining part of said region occupied by the via hole extends outside of the metal pattern.
